(19) United States
(12) Patent Application Publication
(10) Pub. No.: US 2007/0138637 A1
(43) Pub. Date: Jun. 21, 2007

(54) Electronic device having low background luminescence, a black layer, or any combination thereof

(76) Inventor: Shiva Prakash, Santa Barbara, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/311,084

(22) Filed: Dec. 19, 2005

(51) Int. Cl. H01L 23/48; H01J 1/62

(52) U.S. Cl. 257/752; 257/761; 313/500; 257/E33.064

(57) ABSTRACT

An electronic device or a process of forming an electronic device can include a first electrode configured to achieve low L_{background} or include a black layer. An electronic device can include a substrate including a user surface. The electronic device can also include a first electrode that includes a first layer, a second layer, and a third layer. The second layer can lie between the first and third layers, and the first electrode can be configured to achieve low L_{background}. The electronic device can further include a second electrode lying farther from the user surface as compared to the first electrode. In another embodiment, a first electrode can include a first layer and a second layer. The second layer can set the work function of the electrode, and the second layer can be a black layer. Processes can be used to form the electronic devices.

### FIELD OF THE DISCLOSURE

This disclosure relates in general to electronic devices, and more particularly, to an electronic device having low background luminescence, a black layer, or any combination thereof.

### DESCRIPTION OF THE RELATED ART

An electronic device can include a liquid crystal display (“LCD”), an organic light-emitting diode (“OLED”) display, or the like. LCDs and OLED displays are promising technologies for flat panel display applications. Reflected ambient radiation can be a problem to users of the displays. One or more materials used for electrodes within the displays can have mirror-like reflectivity if its thickness is over 20 nanometers. The high reflectivity can result in poor readability or low contrast of the devices in lighted environments, and particularly when used outdoors.

An attempt to solve the reflection problem is to place a circular polarizer in front of an OLED display panel. However, circular polarizers can block about 60% of the emitted light from the OLED and increase module thickness and cost considerably. The polarizer is typically located such that the substrate lies between the polarizer and the OLED.

Another attempt in improving display contrast includes using a light-absorbing material between pixels of an electroluminescent display. The electrodes may lie at locations between such light-absorbing material. Thus, the reflection from one or more electrodes may still be a problem because the electrode(s) may include portions that are as large or larger than the size of a pixel.

### SUMMARY

An electronic device or a process of forming an electronic device can include a first electrode configured to achieve low L_{background} or include a black layer. In a first aspect, an electronic device can include a substrate including a user surface. The electronic device can also include a first electrode that includes a first layer, a second layer, and a third layer. The second layer can lie between the first and third layers, and the first electrode can be configured to achieve low L_{background}. The electronic device can further include a second electrode lying farther from the user surface as compared to the first electrode.

In a second aspect, an electronic device can include a substrate including a user surface. The electronic device can also include a first electrode including a first layer and a second layer. The second layer can set the work function of the electrode, and the second layer can be a black layer. The electronic device can also include a second electrode lying farther from the user surface as compared to the first electrode.

In a third aspect, a process of forming an electronic device can include forming a first electrode over a substrate, wherein the first electrode has low L_{background}. Forming the first electrode can includes forming a first layer, forming a second layer over the first layer, and forming a third layer over the second layer. The process can also include forming a second electrode after forming the first electrode.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of a cross-sectional view of a portion of a substrate after forming first electrodes.

FIG. 2 includes an illustration of a cross-sectional view of the substrate of FIG. 1 after forming an organic layer.

FIG. 3 includes an illustration of a cross-sectional view of the substrate of FIG. 2 after forming a second electrode.

FIG. 4 includes an illustration of a cross-sectional view of the substrate of FIG. 3 after forming a substantially completed electronic device.

FIG. 5 includes an illustration of an alternative embodiment, wherein the first electrodes have a different composition as compared to the first electrodes in FIGS. 1 through 3.

FIGS. 6 through 8 include graphs of luminance, color, and reflectivity, respectively, for an electronic device having a cathode with a Sm layer.

FIGS. 9 through 11 include graphs of luminance, color, and reflectivity, respectively, for an electronic device having an anode with a Ru or Cr layer.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

An electronic device, or a process of forming an electronic device can include a first electrode configured to achieve low L_{background} or include a black layer. In a first aspect, an electronic device can include a substrate including a user surface. The electronic device can also include a first electrode that includes a first layer, a second layer, and a third layer. The second layer can lie between the first and third layers, and the first electrode can be configured to achieve low L_{background}. The electronic device can further include a second electrode lying farther from the user surface as compared to the first electrode.

In one embodiment of the first aspect, the second layer can include a material including Cr, Ru, Ir, Os, Rh, Pt, Pd, Au, or any combination thereof. In another embodiment, the second layer can include a conductive metal oxide. In still another embodiment, the first electrode can be substantially free of an oxide of the second layer. In a further embodiment, each of the first layer and the third layer can include a transparent conductive layer. In still a further embodiment, the first electrode can act as an anode, and the second electrode can act as a cathode. In yet a further embodiment, the electronic device can further include an organic active layer lying between the first and second electrodes.

In a second aspect, an electronic device can include a substrate including a user surface. The electronic device can also include a first electrode including a first layer and a second layer. The second layer can set the work function of the electrode, and the second layer can be a black layer. The electronic device can also include a second electrode lying farther from the user surface as compared to the first electrode.

In one embodiment of the second aspect, the second layer can include a material including Cr, Ru, Ir, Os, Rh, Pt, Pd, Au, or any combination thereof. In another embodiment, the second layer can include a conductive metal oxide. In still another embodiment, the first electrode can be substantially free of an oxide of the second layer. In a further embodiment, the electronic device can further include an organic layer, wherein the organic layer contacts the first electrode, and the organic layer includes an organic active layer. In still a further embodiment, the second layer has a thickness no greater than 10 nm. In yet a further embodiment, the first electrode acts as an anode, and the second electrode acts as a cathode.

In a third aspect, a process of forming an electronic device can include forming a first electrode over a substrate, wherein the first electrode has low L_{background}. Forming the first electrode can include forming a first layer, forming a second layer over the first layer, and forming a third layer over the second layer. The process can also include forming a second electrode after forming the first electrode.

In one embodiment of the third aspect, the second layer can include a material including Cr, Ru, Ir, Os, Rh, Pt, Pd, Au, or any combination thereof. In another embodiment, the process can further include exposing the substrate to an oxygen-containing material, wherein a portion of the second layer reacts to form a conductive metal oxide. In still another embodiment, the process can further include exposing the second layer to an oxygen-containing material, wherein no significant portion of the second layer reacts to form an oxide. In a further embodiment each of the first layer and the third layer includes a transparent conductive layer. In yet a further embodiment, the process can further include forming an organic active layer after forming the first electrode and before forming the second electrodes.

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by Fabrication of Electronic Devices, Operating the Electronic Devices, Benefits, and finally Examples.

### 1. Definitions and Clarification of Terms

Before addressing details of embodiments described below, some terms are defined or clarified. The term “ambient radiation” is intended to mean radiation incident at a user side of an electronic device. Ambient radiation may come from a radiation source outside of the electronic device or may be radiation reflected by a human, wall, or other object outside the electronic device, even though such radiation may originate from within the electronic device.

The terms “array,” “peripheral circuitry,” and “remote circuitry” are intended to mean different areas or components of an electronic device. For example, an array may include pixels, cells, or other structures within an orderly arrangement (usually designated by columns and rows). The pixels, cells, or other structures within the array may be controlled by peripheral circuitry, which may lie on the same substrate as the array but outside the array itself. Remote circuitry typically lies away from the peripheral circuitry and can send signals to or receive signals from the array (typically via the peripheral circuitry). The remote circuitry may also perform functions unrelated to the array. The remote circuitry may or may not reside on the substrate having the array.

The term “black layer” is intended to mean a layer, by itself or in conjunction with one or more other layers, that allows no more than approximately 10% of ambient radiation at a targeted wavelength or spectrum of wavelengths that is incident on an electronic device to be reflected outside the electronic device.

The term “conductive,” with respect to a metal oxide, a metal nitride, or a metal oxynitride is intended to mean a metal-containing material that also includes oxygen, nitrogen, or a combination thereof, wherein such metal-containing material has a bulk resistivity that is no greater than two orders of magnitude higher than a bulk resistivity of such metal-containing material when absent oxygen and nitrogen. For example, RuO₂ is a conductive metal oxide that has a bulk resistivity no greater than two orders of magnitude higher than the bulk resistivity of Ru.

The term “electrically connected,” or any variant thereof, with respect to electronic components, circuits, or portions thereof, is intended to mean that two or more electronic components, circuits, or any combination of at least one electronic component and at least one circuit do not have any intervening electronic component lying between them. Parasitic resistance, parasitic capacitance, or both are not considered electronic components for the purposes of this definition. In one embodiment, electronic components are electrically connected when they are electrically shorted to one another and are at substantially the same voltage. Note that electrically connect includes one or more connections that allow optical signals to be transmitted. For example, electronic components can be electrically connected together using fiber optic lines to allow optical signals to be transmitted between such electronic components.

The term “electrically coupled,” or any variants thereof, is intended to mean an electrical connection, linking, or association of two or more electronic components, circuits, systems, or any combination of: (1) at least one electronic component, (2) at least one circuit, or (3) at least one system in such a way that a signal (e.g., current, voltage, or optical signal) may be transferred from one to another. A non-limiting example of “electrically coupled” can include a direct electrical connection between electronic component(s), circuit(s) or electronic component(s) or circuit(s) with switch(es) (e.g., transistor(s)) electrically connected between them.

The term “electrode” is intended to mean a member, a structure, or a combination thereof configured to transport carriers within an electronic component. For example, an electrode may be an anode, a cathode, a capacitor electrode, a gate electrode, etc. An electrode may include a part of a transistor, a capacitor, a resistor, an inductor, a diode, an electronic component, a power supply, or any combination thereof.

The term “electronic component” is intended to mean a lowest level unit of a circuit that performs an electrical or electro-radiative (e.g., electro-optic) function. An electronic component may include a transistor, a diode, a resistor, a capacitor, an inductor, a semiconductor laser, an optical switch, or the like. An electronic component does not include parasitic resistance (e.g., resistance of a wire) or parasitic capacitance (e.g., capacitive coupling between two conductors electrically connected to different electronic components where a capacitor between the conductors is unintended or incidental).

The term “electronic device” is intended to mean a collection of circuits, electronic components, or combinations thereof that collectively, when properly electrically connected and supplied with the appropriate potential(s), performs a function. An electronic device may include or be part of a system. An example of an electronic device includes a display, a sensor array, a computer system, an avionics system, an automobile, a cellular phone, other consumer or industrial electronic product, or any combination thereof.

The term “high work function” when referring to a layer or material is intended to mean a layer or material having a work function greater than about 4.4 eV.

The term “incident radiation” is intended to mean radiation, including intensity, phase angle, or both of such radiation, at a surface of a layer, member, or structure.

The term “low L_{background}” is intended to mean no more than approximately 30% of the ambient light incident on an electronic device is reflected from the device using the Ambient Contrast Ratio test (discussed later in this specification).

The term “low work function” when referring to a layer or material is intended to mean a layer or material having a work function no greater than about 4.4 eV.

The term “organic active layer” is intended to mean one or more organic layers, wherein at least one of the organic layers, by itself, or when in contact with a dissimilar material, is capable of forming a rectifying junction.

The term “organic layer” is intended to mean one or more layers, wherein at least one of the layers comprises a material including carbon and at least one other element, such as hydrogen, oxygen, nitrogen, fluorine, etc.

The term “outdoors” is intended to mean a location where ambient light significantly varies with the intensity of sunlight or a lack thereof. Note that in addition to being outside of a building, outdoors may also include the interior of a domed stadium having transparent or translucent panels within the dome, as the ambient light level within such domed stadium will significantly vary with the weather, time of day, or both.

The term “radiation-emitting component” is intended to mean an electronic component, which when properly biased, emits radiation at a targeted wavelength or spectrum of wavelengths. The radiation may be within the visible-light spectrum or outside the visible-light spectrum (UV or IR). A light-emitting diode is an example of a radiation-emitting component.

The term “radiation-responsive component” is intended to mean an electronic component, which when properly biased, can respond to radiation at a targeted wavelength or spectrum of wavelengths. The radiation may be within the visible-light spectrum or outside the visible-light spectrum (UV or IR). An IR sensor and a photovoltaic cell are examples of radiation-sensing components.

The term “rectifying junction” is intended to mean a junction within a semiconductor layer or a junction formed by an interface between a semiconductor layer and a dissimilar material, in which charge carriers of one type flow easier in one direction through the junction compared to the opposite direction. A pn junction is an example of a rectifying junction that can be used as a diode.

The term “substrate” is intended to mean a workpiece that can be either rigid or flexible and may include one or more layers of one or more materials, which can include, but are not limited to, glass, polymer, metal or ceramic materials, or combinations thereof.

The term “transparent,” when referring to a layer, material, or structure, is intended to mean that such layer, material, or structure allows at least 70% of radiation at a targeted wavelength or spectrum of wavelengths to be transmitted though such layer, material, or structure.

The term “user surface” is intended to mean a surface of the electronic device principally used during normal operation of the electronic device. In the case of a display, the surface of the electronic device seen by a user would be a user surface. In the case of a sensor or photovoltaic cell, the user surface would be the surface that principally transmits radiation that is to be sensed or converted to electrical energy. Note that an electronic device may have more than one user surface.

The term “visible light spectrum” is intended to mean a radiation spectrum having wavelengths corresponding to 400 to 700 nm.

As used herein, the terms “comprises,” “comprising,” “includes,” “including,” “has,” “having,” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, use of “a” or “an” is employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts. Concepts related to reflection, contrast ratio, and other similar principles are described in more detail in U.S. Patent Application Publication No. 10/658,2362005/0052119 entitled “Organic Electronic Device Having Low Background Luminance” by Yu et al. filed Sep. 8, 2003 (hereinafter “Yu”).

### 2. Fabrication of Electronic Devices

The concepts described herein can be used to determine compositions and thicknesses of layers for electrodes that are configured to achieve low L_{background}. In one embodiment, a thickness of any one or more layers within an electrode can be adjusted to achieve the low L_{background}.

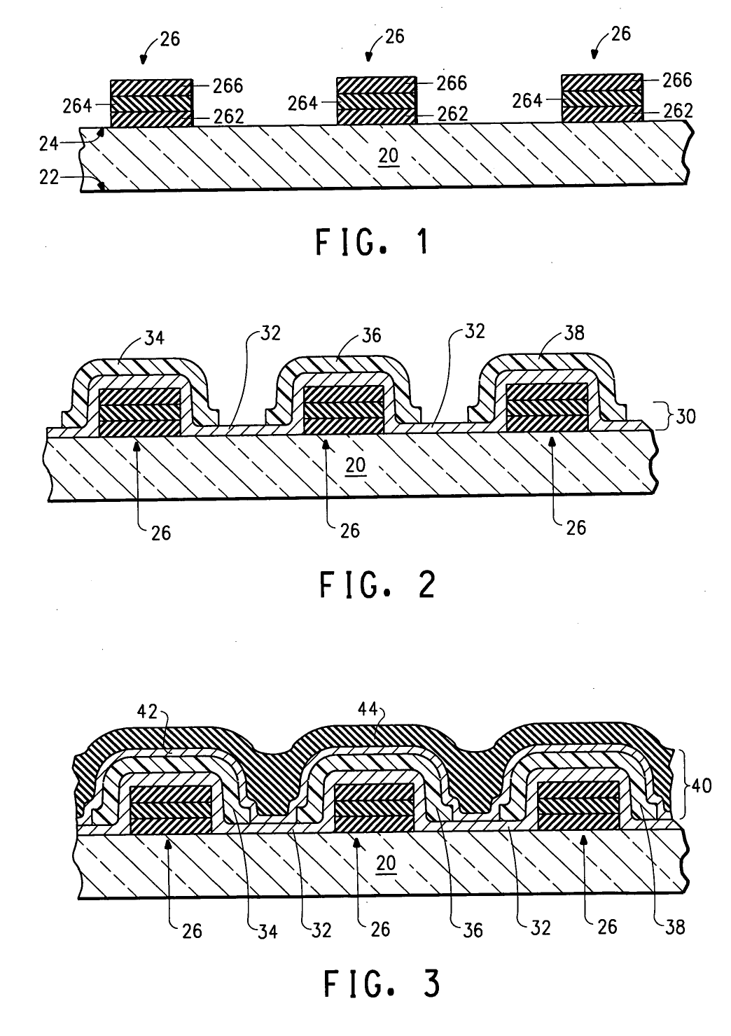

FIG. 1 includes an illustration of a cross-sectional view of a portion of a partially completed electronic device after forming first electrodes 26 over a substrate 20. The substrate 20 can be either rigid or flexible and may include one or more layers of one or more materials, which can include, but are not limited to, glass, polymer, metal or ceramic materials or combinations thereof. In one embodiment, the substrate 20 is substantially transparent to a targeted wavelength or spectrum of wavelengths associated with the electronic device. For example, the electronic device may emit radiation within the visible light spectrum, and thus, the substrate 20 would be transparent to radiation within the visible light spectrum. In another example, the electronic device may respond to infrared radiation, and thus the substrate 20 would be transparent to the infrared radiation.

The substrate 20 includes a user surface 22 and a primary surface 24. The user surface 22 can be the surface of the substrate 20 seen by a user when using the electronic device. The primary surface 24 can be a surface from which at least some of electronic components for the electronic device may be fabricated. Although not illustrated, control circuits may lie within the substrate 20, wherein each control circuit would be electrically connected to a first corresponding electrode 26.

A large number of conductive materials can be used for the first electrodes 26. One or more layers within the first electrodes 26 can include one or more elemental metals (e.g., Cr, Ru, Ir, Os, Rh, Pt, Pd, Au, etc.); metal alloys (e.g., Mg—Al, Li—Al, etc.); conductive metal oxides (e.g., RuO₂, IrO₂, OsOₓ, RhOₓ, etc.); conductive metal alloy oxides (e.g., InSnO, AlZnO, AlSnO, etc.); conductive metal nitrides (e.g., WN, TaN, TiN, etc.); conductive metal alloy nitrides (e.g., TiSiN, TaSiN, etc.); conductive metal oxynitrides; conductive metal alloy oxynitrides; doped Group 14 materials (e.g., C (e.g., nanotubes) Si, Ge, SiC, or SiGe); Group 13 to 15 semiconductor materials (e.g., GaAs, InP, or GaInAs); Group 12 to 16 semiconductor materials (e.g., ZnSe, CdS, or ZnSSe); or any combination thereof.

An elemental metal refers to a layer that consists essentially of a single element and is not a homogenous alloy with another metallic element or a molecular compound with another element. For the purposes of metal alloys, silicon can be considered a metal. In many embodiments, a metal, whether as an elemental metal or as part of a molecular compound (e.g., metal oxide, or metal nitride) may be a transition metal (an element within Groups 3 to 12 in the Periodic Table of the Elements).

In a particular embodiment, a layer within the first electrodes 26 may include a material that is conductive in its oxidized and reduced states (e.g., Ru, Ir, Os, Rh, InSn, AlZn, AlSn, etc.). In another particular embodiment, the layer may not significantly react with oxygen when the layer comes in contact with an oxygen-containing material at a temperature higher than room temperature (e.g., 40° C. or higher) during the formation of the layer and any other subsequent fabrication of the electronic device. The oxygen-containing material may include oxygen, water, or ozone from an ambient that is directed exposed to the layer or diffuses to the layer or may comes from a different adjacent layer. In this particular embodiment, the layer can include Pt, Pd, Au, other suitable oxidation-resistant material, or any combination thereof.

After selecting material for the layers, skilled artisans appreciate that the thickness of the material can be tailored to achieve low L_{background} using the equations in Yu. Although the calculations can yield a single thickness, typically a range of acceptable thicknesses may be given for manufacturing reasons. As long as the thickness does not lie outside the range, reasonably acceptable L_{background} may be achieved.

Skilled artisans appreciate that they may be able to achieve L_{background} and still have acceptable electrical and radiation-related performance for the electronic device. For example, the first electrodes 26 may have a minimum thickness determined by resistance, electromigration, or other device performance or reliability reasons. The maximum thickness may be limited by step-height concerns, such as step coverage or lithography constraints for subsequently-formed layers. Still, the range between the minimum and maximum thicknesses for a layer within the first electrodes 26 may allow a plurality of thicknesses to be chosen that still give low L_{background} while achieving the proper device performance.

In the embodiment as illustrated in FIG. 1, each of the first electrodes 26 includes layers 262, 264, and 266. The layer 266 lies closest to a subsequently-formed organic active layer, and therefore, sets the work function of the first electrodes 26. In one embodiment, the first electrodes 26 can act as anodes, and the work function of the material within the layer 266 may be 4.4 eV or higher. In a particular embodiment, the layer 266 can include mixed-metal oxides of Groups 12, 13 and 14 metals. A non-limiting, specific example of a material for the layer 266 includes indium-tin-oxide (“ITO”), zirconium-tin-oxide (“ZTO”), aluminum-tin-oxide (“ATO”), gold, silver, copper, nickel, selenium, or any combination thereof.

The layer 264 may include a material that is conductive in its oxidized and reduced states (e.g., Ru, Ir, Os, Rh, InSn, AlZn, AlSn, etc.). In another particular embodiment, the layer may not significantly react with oxygen when the layer comes in contact with an oxygen-containing material at a temperature higher than room temperature (e.g., 40° C. or higher) during the formation of the layer and any other subsequent fabrication of the electronic device. The oxygen-containing material may include oxygen, water, or ozone from an ambient that is directly exposed to the layer or diffuses to the layer, or may comes from a different adjacent layer. In this particular embodiment, the layer can include Pt, Pd, Au, other suitable oxidation-resistant material, or any combination thereof. In still another embodiment, the layer 264 can include Cr.

The layer 262 may include one or more of the materials listed with respect to the first electrodes 26. The composition of the layer 262 may be the same or different as compared to each of the layers 264 and 266. In one particular embodiment, the layers 262 and 266 may include substantially the same composition. One or more materials within the layer 264 may not adhere very well to the substrate 20. The layer 262 may act as an adhesion layer between the substrate 20 and the layer 264.

In one embodiment, radiation at a targeted wavelength or spectrum of wavelengths is to be transmitted through the first electrodes 26. Thus, the thicknesses of the layers within first electrodes 26 are not too thick, so that a significant portion of radiation at a targeted wavelength or spectrum of wavelengths can be transmitted through the first electrodes 26. Also, the thickness of the layer 262, 264, 266, or any combination thereof may be adjusted to achieve low L_{background}. Thus, by having three layers instead of two, more flexibility can be obtained in choosing thicknesses and still achieving the low L_{background}. In a particular embodiment, transmission or reflection by the first electrodes 26 of radiation at a targeted wavelength or spectrum of wavelengths may not be optimized in order to achieve low L_{background}.

In one embodiment, the first electrodes 26 can have a thickness in a range of approximately 10 to 500 nm. In a particular embodiment, the layer 264 can have a thickness no greater than 10 nm, and in another embodiment, can have a thickness of at least 2 nm. In another particular embodiment, the layer 264 may have thickness no greater than 6 nm, and in a more particular embodiment, may have a thickness no greater than 4 nm. The layer 264 may have the same thickness or different thicknesses within the different sub-pixels of the same pixel.

In one embodiment, the first electrodes 26 are formed by placing a stencil mask over the substrate 20 and using a conventional or proprietary physical vapor deposition technique to deposit the first electrodes 26 as illustrated in FIG. 1. In another embodiment, the first electrodes 26 are formed by blanket depositing any individual or combination of the layers 262, 264, and 266 for the first electrodes 26. A masking layer (not illustrated) is then formed over portions of the layer(s) that are to remain to form first electrodes 26. A conventional or proprietary etching technique is used to remove exposed portions of the layer(s) and leave the first electrodes 26. After the etching, the masking layer is removed using a conventional or proprietary technique.

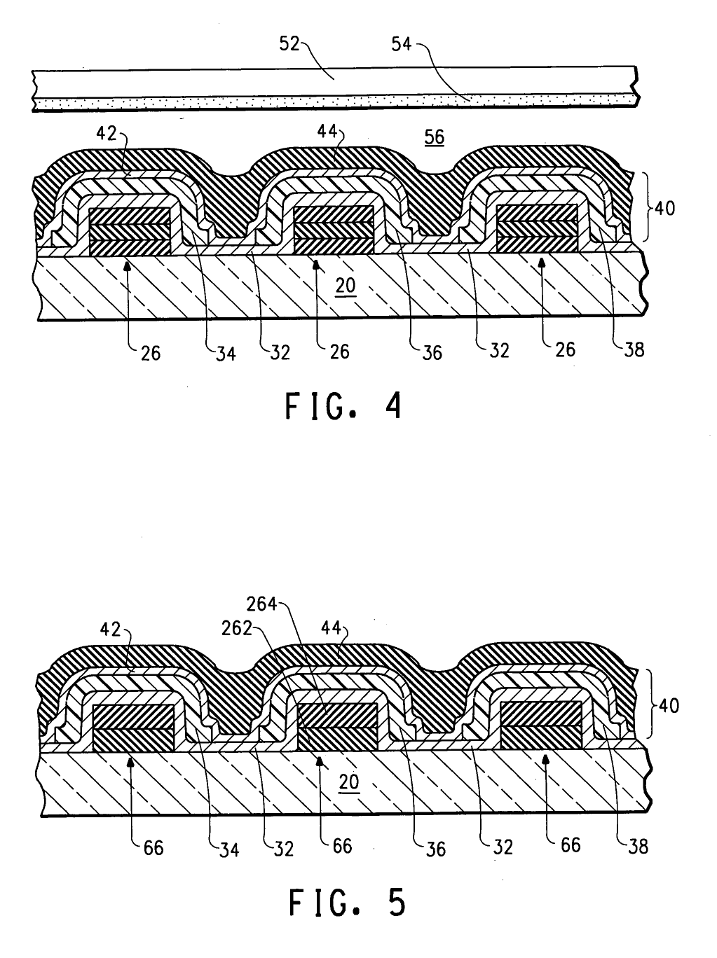

An organic layer 30 is formed over the first electrodes 26 and substrate 20 as illustrated in FIG. 2. The organic layer 30 may include one or more layers. For example, the organic layer can include an organic active layer, a buffer layer, an electron-injection layer, an electron-transport layer, an electron-blocking layer, a hole-injection layer, a hole-transport layer, or a hole-blocking layer, or any combination thereof. In one embodiment, the organic layer 30 may include a first organic layer 32 and organic active layers 34, 36, and 38.

Any individual or combination of layers within the organic layer 30 can be formed by a conventional or proprietary technique, including spin coating, vapor depositing (chemical or physical), printing (ink jet printing, screen printing, solution dispensing (dispensing the liquid composition in strips or other predetermined geometric shapes or patterns, as seen from a plan view), or any combination thereof), other depositing technique, or any combination thereof for appropriate materials as described below. Any individual or combination of layers within the organic layer 30 may be cured after deposition.

As illustrated in FIG. 2, the first organic layer 32 may act as a buffer layer, an electronic-blocking layer, a hole-injection layer, a hole-transport layer, or any combination thereof. In one embodiment, the first organic layer includes a single layer, and in another embodiment, the first organic layer 32 can include a plurality of layers. The first organic layer 32 may include one or more materials that may be selected depending on the function the first organic layer 32 is to provide. In one embodiment, if the first organic layer 32 is to act as a buffer layer, the first organic layer may include a conventional or proprietary material that is suitable for use in a buffer layer, as used in an OLED display. In another embodiment, if the first organic layer 32 is to act as a hole-transport layer, the first organic layer may include a conventional or proprietary material that is suitable for use in a hole-transport layer. In one embodiment, the thickness of the first organic layer 32 may have a thickness in a range of approximately 50 to 300 nm, as measured over the substrate 20 at a location spaced apart from the first electrodes 26. In another embodiment, the first organic layer 32 may be thinner or thicker than the range recited above.

The composition of the organic active layer 34, 36, 38, or any combination thereof can depend upon the application of the electronic device. In one embodiment, the organic active layers 34, 36, and 38 are used in radiation-emitting components. In a particular embodiment, the organic active layer 34 can include a blue light emitting material, the organic active layer 36 can include a green light emitting material, and the organic active layer 38 can include a red light emitting material. Although not illustrated, a structure (e.g., a well structure, cathode separators, or the like) may lie between the first electrodes 26 to reduce the likelihood of materials from different organic active layers from contacting each other at locations above the first electrodes 26. For a monochromatic display, the organic active layers 34, 36, and 38 may have substantially the same composition. In another embodiment, the organic active layers 34, 36, and 38 can be replaced by an organic active layer that is substantially continuous over the portion of the substrate 20 illustrated in FIG. 2. In another embodiment, the organic active layer 34, 36, 38, or any combination thereof may be used in a radiation-responsive component, such as a radiation sensor, photovoltaic cell, or the like.

Each of the organic active layers 34, 36, and 38 can include material(s) conventionally used as organic active layers in organic electronic devices and can include one or more small molecule materials, one or more polymer materials, or any combination thereof. After reading this specification, skilled artisans will be capable of selecting appropriate material(s), layer(s) or both for each of the organic active layers 34, 36, and 38. In one embodiment, each of the organic active layers 34, 36, and 38 has a thickness in a range of approximately 40 to 100 nm, and in a more specific embodiment, in a range of approximately 70 to 90 nm.

In an alternative embodiment, the organic layer 30 may include a single layer with a composition that varies with thickness. For example, the composition nearest the first electrodes 26 may act as a hole transporter, the next composition may act as an organic active layer, and the composition furthest from the first electrodes 26 may act as an electron transporter. Similarly, the function of charge injection, charge blocking, or any combination of charge injection, charge transport, and charge blocking can be incorporated into the organic layer 30. One or more materials may be present throughout all or only part of the thickness of the organic layer.

Although not illustrated, a hole-blocking layer, an electronic-injection layer, an electron-transport layer, or any combination thereof may be part of the organic layer 30 and formed over the organic active layers 34, 36, and 38. The electron-transport layer can allow electrons to be injected from the subsequently-formed second electrode (i.e., cathode) and transferred to the organic active layers 34, 36, and 38. The hole-blocking layer, electronic-injection layer, electron-transport layer, or any combination thereof typically has a thickness in a range of approximately 30 to 500 nm.

Any one or more of the layers within the organic layer 30 may be patterned using a conventional or proprietary technique to remove portions of the organic layer 30 where electrical contacts (not illustrated) are subsequently made. Typically, the electrical contact areas are near the edge of the array or outside the array to allow peripheral circuitry to send or receive signals to or from the array.

A second electrode 40 is formed over the organic layer 30 as illustrated in FIG. 3. In one embodiment, the second electrode 40 can act as a cathode. The array of the electronic device can have one or more common cathodes, wherein each common cathode is shared by a plurality of electronic components. In still another embodiment (not illustrated), the second electrode 40 can include one cathode for each electronic radiation-emitting or radiation-responsive component within the array.

In one embodiment, the second electrode 40 can include a low work function layer 42 and a conductive layer 44 that helps to provide good conductivity. The low work function layer 42 can include a Group 1 metal (e.g., Li, Cs, etc.), a Group 2 (alkaline earth) metal, a rare earth metal, including the lanthanides and the actinides, an alloy including any of the foregoing metals, or any combination thereof. A conductive polymer with a low work function may also be used. Conductive layer 44 may include nearly any conductive material, including those previously described with respect to the first electrode 26. The conductive layer 44 is used primarily for its ability to allow current to flow while keeping resistance relatively low. An exemplary material for conductive layer 44 includes aluminum, silver, copper, or any combination thereof.

The second electrode 40 can be formed using any one or more of the formation techniques described with respect to the first electrodes 26. In many applications, the thickness of the second electrode 40 may be in a range of approximately 5 to 500 nm. If radiation is not to be transmitted through the second electrode 40, the upper limit on the thickness may be greater than 500 nm.

Other circuitry not illustrated, may be formed using any number of the previously described or additional layers. Although not illustrated, additional insulating layer(s) and interconnect level(s) may be formed to allow for circuitry in peripheral areas (not illustrated) that may lie outside the array. Such circuitry may include row or column decoders, strobes (e.g., row array strobe, column array strobe, or the like), sense amplifiers, or any combination thereof.

A lid 52 with a desiccant 54 is attached to the substrate 20 at locations (not illustrated in FIG. 4) outside the array to form a substantially completed electronic device. A gap 56 may or may not lie between the second electrode 40 and the desiccant 54. The materials used for the lid and desiccant and the attaching process are conventional or proprietary. The lid 52 typically lies on a side of the electronic device opposite the user side of the electronic device. Still, if desired, radiation may be transmitted through the lid 52 instead of or in conjunction with the substrate 20. If so, the lid 52 and desiccant 54 can be designed to allow sufficient radiation to pass through.

In other embodiments, the first and second electrodes 26 and 40 can be reversed. In this embodiment, the second electrode 40 would like closer to the user side 22 of the substrate 20, as compared to the first electrodes 26. The second electrode 40 could include a plurality of second electrodes that are each connected to control circuits (not illustrated). Also, the first electrodes 26 could be replaced by a common first electrode. In still another alternative embodiment, the control circuits may be connected to one type of electrode that lie farther from the substrate 20 as compared to the other type of electrode.

### 3. Operating the Electronic Devices

During operation of a display, appropriate potentials are placed on the first and second electrodes 26 and 40 to cause radiation to be emitted from the organic layer 30. More specifically, when light is to be emitted, a potential difference between the first and second electrodes 26 and 40 allows electron-hole pairs to combine within the organic layer 30, so that light or other radiation may be emitted from the electronic device. In a display, rows and columns can be given signals to activate the appropriate pixels to render a display to a viewer in a human-understandable form.

During operation of a radiation detector, such as a photodetector, sense amplifiers may be coupled to the first electrodes 26 or the second electrode 40 of the array to detect significant current flow when radiation is received by the electronic device. In a voltaic cell, such as a photovoltaic cell, light or other radiation can be converted to energy that can flow without an external energy source. After reading this specification, skilled artisans are capable of designing the electronic devices, peripheral circuitry, and potentially remote circuitry to best suit their particular needs.

### 4. Alternative Embodiments

In another embodiment, the layer 266 is not present. In this particular layer, the layer 264 can set the work function for electrodes 66, as illustrated in FIG. 5. The layer 264 can have any of one or more of the materials and thicknesses as previously described. The layer 264 can act as a black layer. The layer 264 may be in direct contact with the organic layer 30 that can include the first organic layer 32, organic active layers 34, 36, 38, or any combination thereof.

### 5. Benefits

After reading this specification, skilled artisans will appreciate the composition, thickness, or both for each layer or combination of layers within the first electrodes 26 may be adjusted to achieve low L_{background}. Any individual or combination layers within the electronic device can be used in performing calculations described above. In one embodiment, only one of the layers within the first electrodes 26 may be considered, and in another embodiment, only a combination of layers within the first electrodes 26 may be considered.

In one embodiment, the layer 264 can include a number of different materials that are not adversely affected by the presence of oxygen at an elevated temperature (higher than room temperature). In one particular embodiment, the material may react with oxygen (from an ambient or another material immediately adjacent to it) at an elevated temperature to form a conductive metal oxide. In another particular embodiment, the material may not significantly react with oxygen at an elevated temperature, as seen during formation a layer including such material or subsequent thereto.

In one embodiment, the layer 264 may directly contact the organic layer 30. In a particular embodiment, the first organic layer 32 may be corrosive. For example, the first organic layer may include PEDOT-PSS or PANI-PSS. The layer 264 can include a material that is not readily corroded (e.g., is not significantly oxidized) or is not adversely affected by such corrosion (e.g., can form a conductive metal oxide, nitride, or oxynitride). If the layer 266 would be present and include ITO, it may be more likely to be adversely affected by a corrosive layer in contact with layer 266.

The thickness of the layer 264 may be substantially uniform and be selected to act as a resonance cavity tuned for blue light. Such a thickness for the layer 264 can help to improve the intensity of blue light emitted from the electronic device. The intensity of green light and red light emitted from the electronic device may be less, however, the lower green and red intensity can be compensated for by driving the green light-emitting components and red-light emitting components a little harder (e.g., more current). In still another embodiment, the layer 264 may have different thicknesses for each of the blue, green, and red light-emitting components.

Embodiments as described herein can provide a cost-effective, manufacturable solution to provide low L_{background} compared to conventional electronic devices because existing materials may be used within an electronic device without requiring the replacement of current materials within the electronic device regions. The ability to use the current materials simplifies integration and reduces the likelihood of device re-design, materials compatibility or device reliability issues.

The embodiments as described herein can be adapted to many applications and provide a cost-effective, manufacturable solution to provide relatively higher contrast compared to conventional electronic devices. The embodiments may obviate the need for a circular polarizer. Low L_{background} can be achieved by designing the electric device for low reflectivity. The layers affected do not significantly affect the overall thickness of the electronic device.

### EXAMPLES

The concepts described herein will be further described in the following examples, which do not limit the scope of the invention described in the claims. In the examples below, an anode is demonstrated to have a greater impact on low L_{background}, as compared to a cathode. The cathode information is provided in Example 1, and the anode information is provided in Example 2.

### Example 1

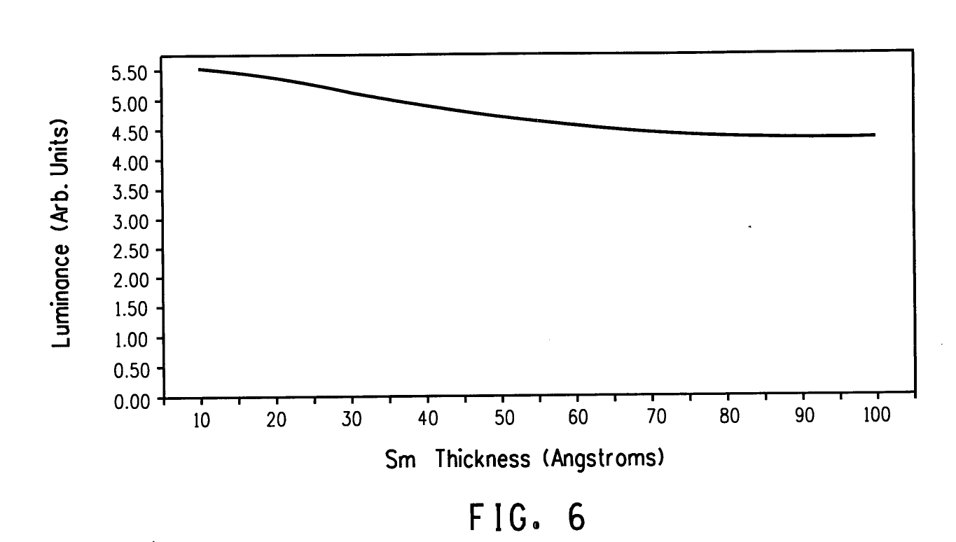

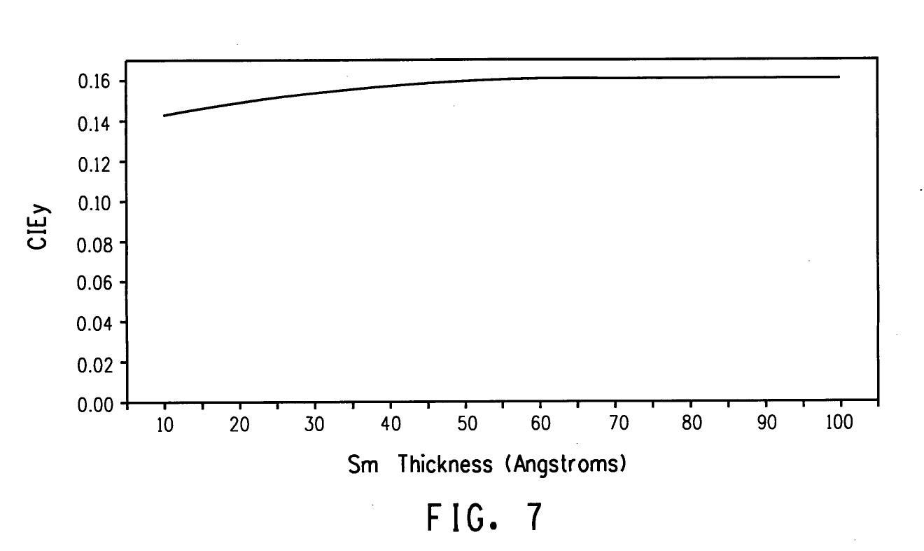

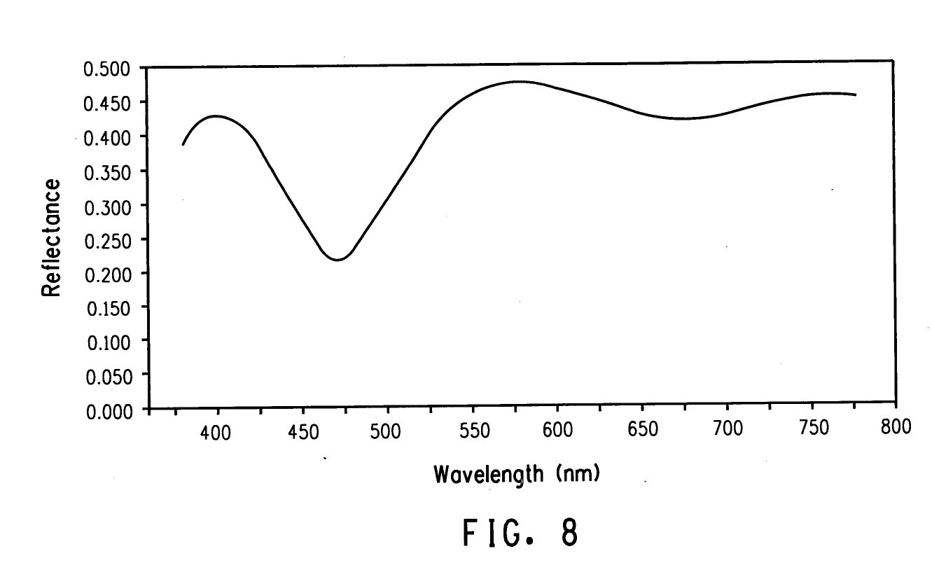

Example 1 demonstrates that the composition, thickness, or both of one or more layers within a cathode may not be well suited to achieve low L_{background}. An electronic device can be fabricated with a cathode that includes a Sm layer in the cathode. The cathode can include a sandwich of Ba/Al/Sm/Al or LiF/Al/Sm/Al, depending on whether Ba or LiF is used as the low work function layer. FIGS. 6 through 8 include graphs for luminance, ClEy (color), and reflectance for the cathode including the Sm layer. The luminance and color properties at varying thicknesses of the Sm layer are acceptable, but the minimum reflectance is relatively high and at a frequency (approximately 470 nm) within the blue light spectrum. The minimum reflectance is higher than 20%. The human eye has less sensitivity to radiation within the blue light spectrum (400 to 500 nm) as compared to the green light spectrum (500 to 600 nm).

### Example 2

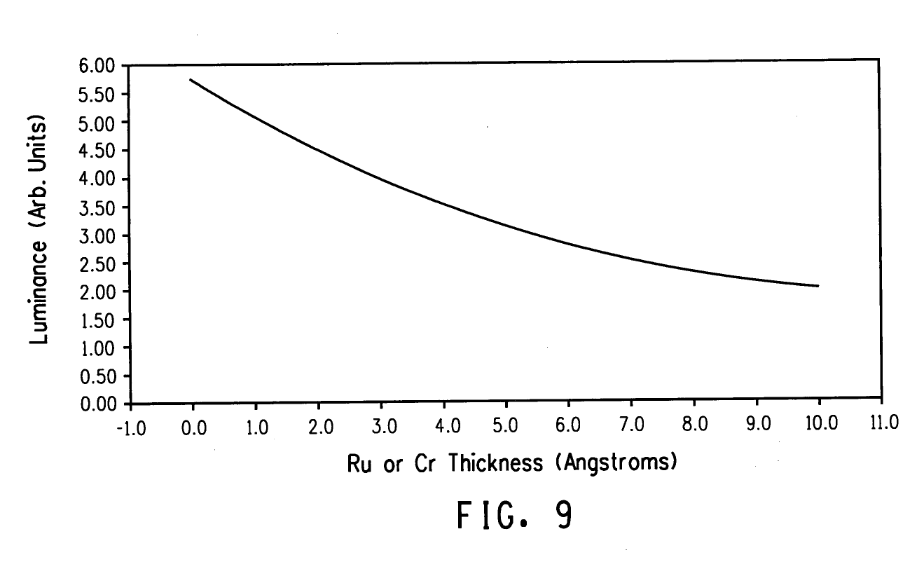

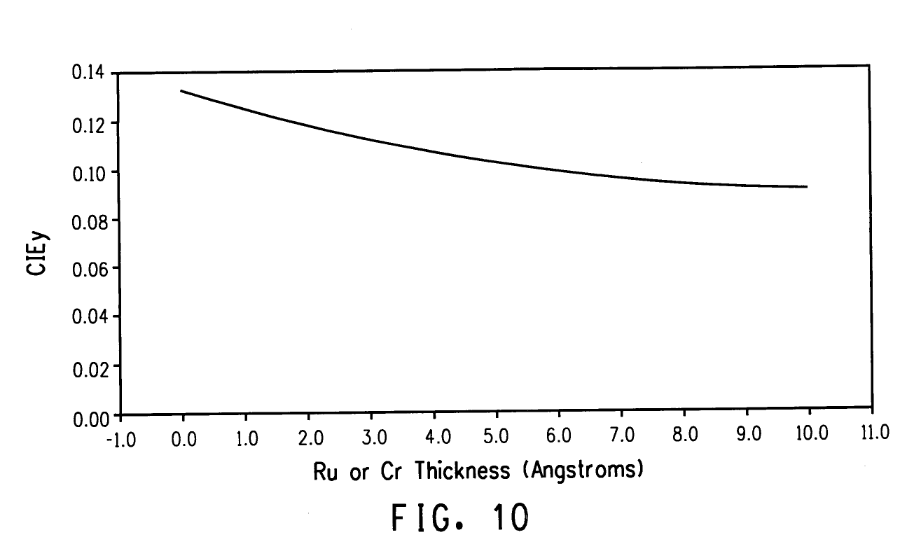

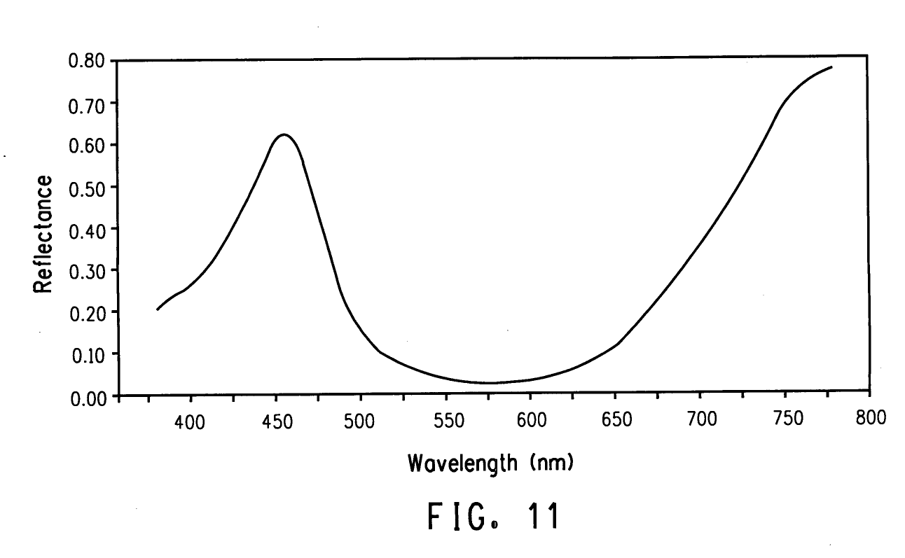

Example 2 demonstrates that the composition, thickness or both of one or more layers within an anode may be more effective to achieve low L_{background} as compared to the cathode in Example 1. An electronic device can be fabricated with a cathode that includes a Ru or Cr layer in the anode. The anode can include a sandwich of ITO/Ru/ITO or ITO/Cr/ITO. FIGS. 9 through 11 include graphs for luminance, ClEy, and reflectance for the anode including the Ru or Cr layer. Luminance is not as good for the cathode in Example 1. However, the color improves and the minimum reflectance is significantly lower, and is very low in the eye sensitivity range, which corresponds to the green light spectrum (wavelength range 500 to 600 nm). The minimum reflectance is less than 10%, and in a particular embodiment is less than 5%. Thus, the anode of Example 2 achieves a lower L_{background} than the cathode of Example 1.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

What is claimed is:

1. An electronic device comprising:
a substrate including a user surface;
a first electrode including a first layer, a second layer, and a third layer, wherein:
the second layer lies between the first and third layers; and
the first electrode is configured to achieve low L_{background}; and
a second electrode lying farther from the user surface as compared to the first electrode.

2. The electronic device of claim 1, wherein the second layer comprises a material including Cr, Ru, Ir, Os, Rh, Pt, Pd, Au, or any combination thereof.

3. The electronic device of claim 1, wherein the second layer includes a conductive metal oxide.

4. The electronic device of claim 1, wherein the first electrode is substantially free of an oxide of the second layer.

5. The electronic device of claim 1, wherein each of the first layer and the third layer includes a transparent conductive layer.

6. The electronic device of claim 1, wherein:
the first electrode acts as an anode; and
the second electrode acts as a cathode.

7. The electronic device of claim 1, further comprising an organic active layer lying between the first and second electrodes.

8. An electronic device comprising:
a substrate including a user surface;
a first electrode including a first layer and a second layer, wherein:
the second layer sets the work function of the electrode; and
the second layer is a black layer; and
a second electrode lying farther from the user surface as compared to the first electrode.

9. The electronic device of claim 8, wherein the second layer comprises a material including Cr, Ru, Ir, Os, Rh, Pt, Pd, Au, or any combination thereof.

10. The electronic device of claim 8, wherein the second layer includes a conductive metal oxide.

11. The electronic device of claim 8, wherein the first electrode is substantially free of an oxide of the second layer.

12. The electronic device of claim 8, further comprising an organic layer, wherein:
the organic layer contacts the first electrode; and
the organic layer includes an organic active layer.

13. The electronic device of claim 8, wherein the second layer has a thickness no greater than 10 nm.

14. The electronic device of claim 8, wherein:
the first electrode acts as an anode; and
the second electrode acts as a cathode.

15. A process of forming an electronic device comprising:
forming a first electrode over a substrate, wherein the first electrode has low L_{background}, and forming the first electrode comprises:
forming a first layer;
forming a second layer over the first layer; and
forming a third layer over the second layer; and
forming a second electrode after forming the first electrode.

16. The process of claim 15, wherein the second layer comprises a material including Cr, Ru, Ir, Os, Rh, Pt, Pd, Au, or any combination thereof.

17. The process of claim 15, further comprising exposing the substrate to an oxygen-containing material, wherein a portion of the second layer reacts to form a conductive metal oxide.

18. The process of claim 15, further comprising exposing the second layer to an oxygen-containing material, wherein no significant portion of the second layer reacts to form an oxide.

19. The process of claim 15, wherein each of the first layer and the third layer includes a transparent conductive layer.

20. The process of claim 15, further comprising forming an organic active layer after forming the first electrode and before forming the second electrodes.
